(19) United States
(12) Patent Application Publication
(10) Pub. No.: US 2015/0371956 A1
(43) Pub. Date: Dec. 24, 2015

(54) CRACKSTOPS FOR BULK SEMICONDUCTOR WAFERS

(71) Applicant: GLOBALFOUNDRIES Inc., Grand Cayman (KY)

(72) Inventors: Rahul Agarwal, Waterford, NY (US); Shun Qiang Gong, Singapore (SG)

(21) Appl. No.: 14/309,024

(22) Filed: Jun. 19, 2014

(51) Int. Cl. H01L 23/00; H01L 21/283; H01L 21/3065

(52) U.S. Cl. CPC H01L 23/562; H01L 21/3065; H01L 21/283

(57) ABSTRACT

Embodiments of the present invention provide crackstops for bulk semiconductor wafers and methods of fabrication. A die level crackstop is formed as a trench within the wafer around each die. A wafer level crackstop includes one or more trenches formed as rings around the periphery of the wafer near the wafer edge. These crackstops serve to prevent damage during handling of ultra thin wafers and dicing of individual ICs, thereby improving product yield.

### FIELD OF THE INVENTION

The present invention relates generally to semiconductor fabrication, and more particularly, to formation of crackstops.

### BACKGROUND

In the fabrication of semiconductor integrated circuits (ICs), multiple ICs are simultaneously fabricated on a semiconductor wafer by lithographic techniques. Various fabrication processes including deposition, etching, and polishing are performed to make the functional ICs. The ICs are typically arranged in a grid pattern on the semiconductor wafer. As part of the fabrication process, individual ICs are separated from the wafer by dicing the wafer along the dicing lanes with either a saw or laser to form IC chips or dies, and may then be placed in packages to form the final product. In semiconductor fabrication, yield is an important factor for consideration.

### SUMMARY

Embodiments of the present invention provide crackstops for bulk semiconductor wafers and methods of fabrication. A die level crackstop is formed as a trench within the wafer around each die. A wafer level crackstop includes one or more trenches formed as rings around the periphery of the wafer near the wafer edge. These crackstops serve to prevent damage during handling of ultra thin wafers and dicing of individual ICs, thereby improving product yield.

In a first aspect, embodiments of the present invention provide a method for preventing damage in a bulk semiconductor wafer, comprising: forming at least one trench within a periphery of the semiconductor wafer; and filling the at least one trench with a fill material.

In a second aspect, embodiments of the present invention provide a method for preventing damage in a bulk semiconductor wafer comprising a plurality of die, the method comprising: forming a die crackstop trench around each die; forming a first wafer crackstop trench around a periphery of the semiconductor wafer; and filling the die crackstop trench and the first wafer crackstop trench with a fill material.

In a third aspect, embodiments of the present invention provide a method for preventing damage in a bulk semiconductor wafer comprising a plurality of die, the method comprising: forming a die crackstop trench around each die; forming a wafer crackstop trench around a periphery of the semiconductor wafer; filling the die crackstop trench with a first fill material; and filling the wafer crackstop trench with a second fill material.

### BRIEF DESCRIPTION OF THE DRAWINGS

The drawings are not necessarily to scale. The drawings are merely representations, not intended to portray specific parameters of the invention. The drawings are intended to depict only typical embodiments of the invention, and therefore should not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines, which would otherwise be visible in a “true” cross-sectional view, for illustrative clarity. Furthermore, for clarity, some reference numbers may be omitted in certain drawings.

FIG. 1A is a semiconductor wafer at a starting point for embodiments of the present invention.

FIG. 1B is a semiconductor wafer after a subsequent process step of thru-silicon via (TSV) cavity etch and wafer crackstop trench (CST) cavity formation.

FIG. 1C is a semiconductor wafer after a subsequent process step of filling TSV cavities and wafer CST cavities.

FIG. 1D is a semiconductor wafer after a subsequent process step of forming a BEOL stack.

FIG. 1E is a semiconductor wafer after a subsequent process step of wafer edge trimming.

FIG. 1F is a semiconductor structure after subsequent process steps of affixing a carrier wafer and backside thinning.

FIG. 2A is a semiconductor wafer at a starting point for alternative embodiments of the present invention.

FIG. 2B is a semiconductor wafer after a subsequent process step of TSV cavity etch.

FIG. 2C is a semiconductor wafer after a subsequent process step of filling TSV cavities.

FIG. 2D is a semiconductor wafer after a subsequent process step of forming wafer CST cavities.

FIG. 2E is a semiconductor wafer after a subsequent process step of filling wafer CST cavities.

FIG. 3A is a top-down view of a semiconductor wafer in accordance with embodiments of the present invention.

FIG. 3B is a cross section of the semiconductor structure shown in FIG. 3A along line A-A′.

FIG. 4 is a flowchart indicating process steps for embodiments of the present invention.

FIG. 5 is a flowchart indicating process steps for alternative embodiments of the present invention.

### DETAILED DESCRIPTION

Exemplary embodiments will now be described more fully herein with reference to the accompanying drawings, in which exemplary embodiments are shown. It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art.

The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, are interchangeable and specify the presence of stated features, regions, integers, steps, operations, elements, and/or components, but do not preclude the presence or addition of one or more other features, regions, integers, steps, operations, elements, components, and/or groups thereof. As used herein, “include” shall have the same meaning as “comprise”.

Reference throughout this specification to “one embodiment,” “an embodiment,” “embodiments,” “exemplary embodiments,” “some embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment. It will be understood that one skilled in the art may cross embodiments by “mixing and matching” one or more features of one embodiment with one or more features of another embodiment.

The terms “overlying” or “atop”, “positioned on” or “positioned atop”, “underlying”, “beneath” or “below” mean that a first element, such as a first structure, e.g., a first layer, is present on a second element, such as a second structure, e.g. a second layer, wherein intervening elements, such as an interface structure, e.g. interface layer, may be present between the first element and the second element.

Embodiments of the present invention provide crackstops for bulk semiconductor wafers and methods of fabrication. A die level crackstop (“die CST”) is formed as a trench within the wafer around each die. A wafer level crackstop (“wafer CST”) includes one or more trenches formed as rings around the periphery of the wafer near the wafer edge. These crackstops serve to prevent damage during handling of ultra thin wafers and dicing of individual ICs, thereby improving product yield.

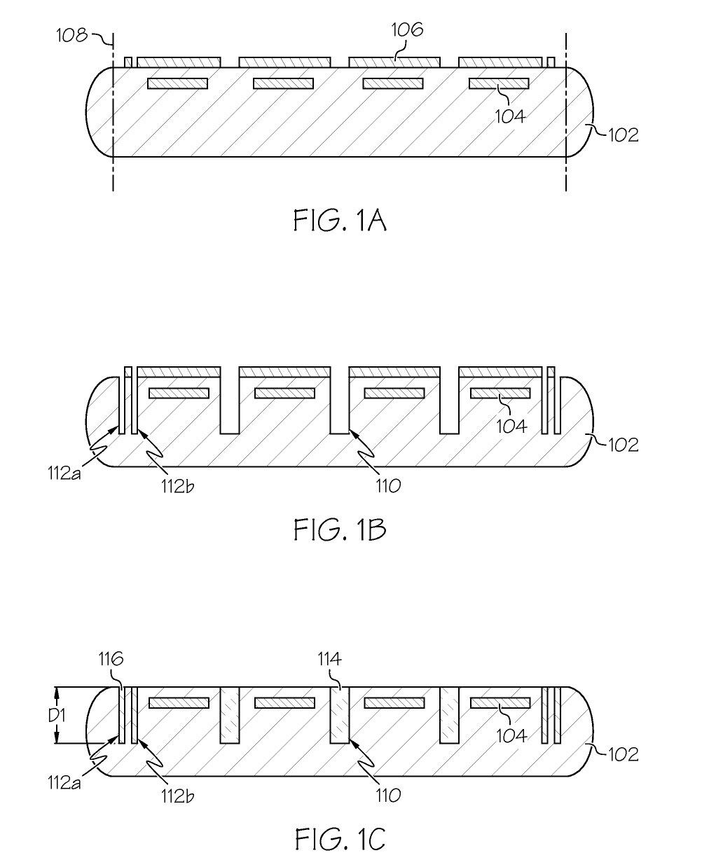

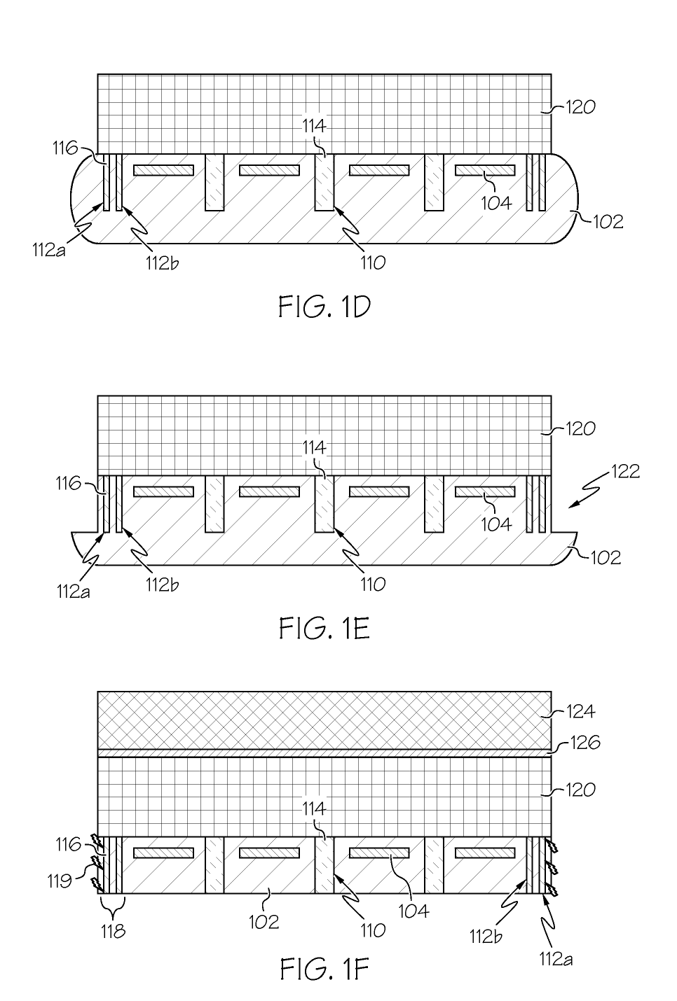

FIG. 1A is a semiconductor wafer at a starting point for embodiments of the present invention. Wafer 102 has functional integrated circuit 104. A first resist layer 106 is deposited over the wafer, and patterned to expose area(s) of the wafer 102 where TSVs (through silicon vias), die CSTs (crackstop trenches), and wafer CSTs are to be formed. Line 108 represents the trim line, where the wafer 102 will later be trimmed.

FIG. 1B is a semiconductor wafer after a subsequent process step of TSV cavity etch and wafer CST cavity formation. In embodiments, at least one of a TSV cavity, a die CST, and a wafer CST is formed in the wafer 102. In embodiments, a plurality and/or each of the TSV cavities, die CST cavities, and wafer CST cavities are formed simultaneously. In the example shown in FIG. 1B, wafer CSTs 112a and 112b are shown. TSV cavities are also shown, an example of which is pointed out at reference number 110. In embodiments, wafer CSTs (such as 112a and 112b) are circular and formed in the periphery of the wafer 102 (i.e. going around the perimeter of the wafer). Wafer CST 112b is concentrically located within CST 112a. In embodiments, one to four wafer CSTs, or any suitable number, may be present. In embodiments, the TSV cavities and wafer CSTs (and/or die CSTs) may be formed by anisotropic etch process, such as a deep reactive ion etch (RIE) process.

FIG. 1C is a semiconductor wafer after a subsequent process step of filling TSV cavities and wafer CSTs. The TSV cavities 110 are filled with material 114, now forming TSVs. Wafer CSTs 112a, 112b are filled with material 116. Material 114 and material 116 may be the same material or may differ from one another. In embodiments, material 114 and/or material 116 may be copper (Cu), tungsten (W), aluminum (Al), titanium (Ti), amorphous silicon, polysilicon, silicon oxide (SiO2), and/or another suitable material. The depth of the wafer CSTs 112a, 112b is represented as D1. In embodiments, D1 may range from about 10 microns to about 100 microns. After filling, the resist layer 106 is removed. Filled wafer CSTs function as a crackstop.

FIG. 1D is a semiconductor wafer after a subsequent process step of forming a BEOL stack. A back-end-of-line (BEOL) stack 120 is formed over wafer 102.

FIG. 1E is a semiconductor wafer after a subsequent process step of wafer edge trimming. As depicted, the edge, shown generally at 122, of wafer 102 is trimmed. During this process, the wafer CSTs 112a and 112b prevent damage to the edges of the wafer during subsequent processing.

FIG. 1F is a semiconductor structure after subsequent process steps of affixing a carrier wafer and backside thinning A carrier wafer 124 is bonded to the BEOL stack 120 by adhesive layer 126. The backside of the wafer 102 is thinned, exposing the material 114-filled TSV cavities 110 and material 116-filled wafer CSTs 112a and 112b.

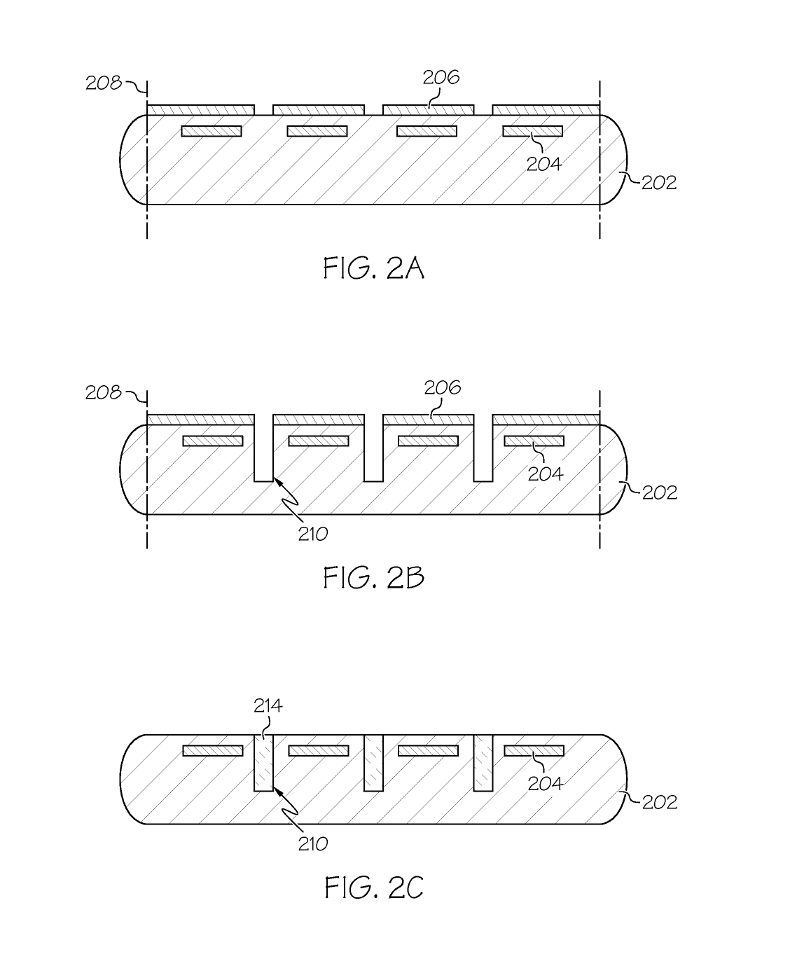

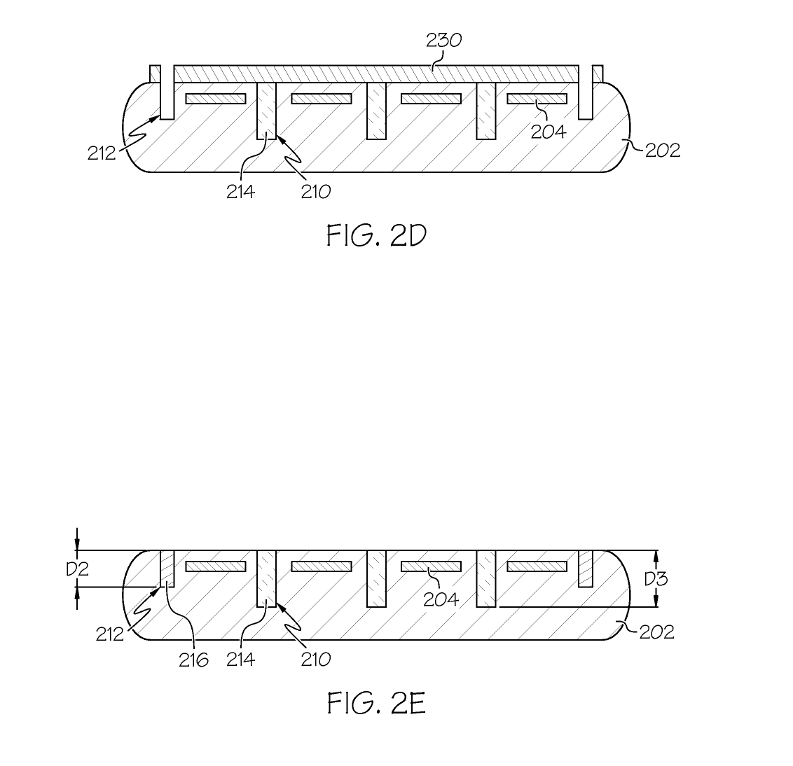

FIG. 2A is a semiconductor wafer at a starting point for alternative embodiments of the present invention. Wafer 202 has functional integrated circuit 204. A first resist layer 206 is deposited over the wafer 202, and patterned to expose area(s) of the wafer 202 where TSV cavities are to be formed. Line 208 represents the trim line, where the wafer 202 will later be trimmed.

FIG. 2B is a semiconductor wafer after a subsequent process step of TSV cavity etch. At least one TSV cavity 210 is formed in the wafer 202. In embodiments, the TSVs and wafer CSTs may be formed by anisotropic etch process, such as a deep RIE process.

FIG. 2C is a semiconductor wafer after a subsequent process step of filling TSV cavities. The TSV cavities 210 are shown filled with material 214 to form TSVs. In embodiments, material 214 may be copper (Cu), tungsten (W), aluminum (Al), and/or other suitable material. After the filling, the resist layer 206 is removed.

FIG. 2D is a semiconductor wafer after a subsequent process step of forming at least one wafer CST. A second resist layer 230 is deposited over the top of wafer 202, and patterned to expose area(s) of the wafer 202 where the at least one wafer CST is to be formed. At least one wafer CST 212 is then formed by anisotropic etch process, such as a deep RIE process. Another suitable process may be substituted without departing from the scope of the invention.

FIG. 2E is a semiconductor wafer after a subsequent process step of filling the wafer CST. The wafer CST 212 is shown filled with material 216 to form a crackstop. In embodiments, material 216 may be a non-metal fill substance. The non-metal fill substance may include, but is not limited to, amorphous silicon, polysilicon, silicon oxide, silicon nitride, silicon oxycarbide, and silicon oxynitride. In other embodiments, material 216 may be a non-copper metal, including, but not limited to, titanium, tungsten, and aluminum. In embodiments, material 216 may be the same as, or different from, material 214. After the filling, the second resist 230 is removed. D2 represents the depth of the wafer CST 212, and D3 represents the depth of TSV cavities 210. In embodiments, D2 may be less than or equal to D3. Additional barrier layers (not shown) may be present in the TSV cavities, wafer CSTs, and die CSTs to prevent metal diffusion. In embodiments, D2 ranges from about 2 microns to about 30 microns, and D3 ranges from about 10 microns to about 100 microns. From this point forward, steps are similar to FIGS. 1D-1F.

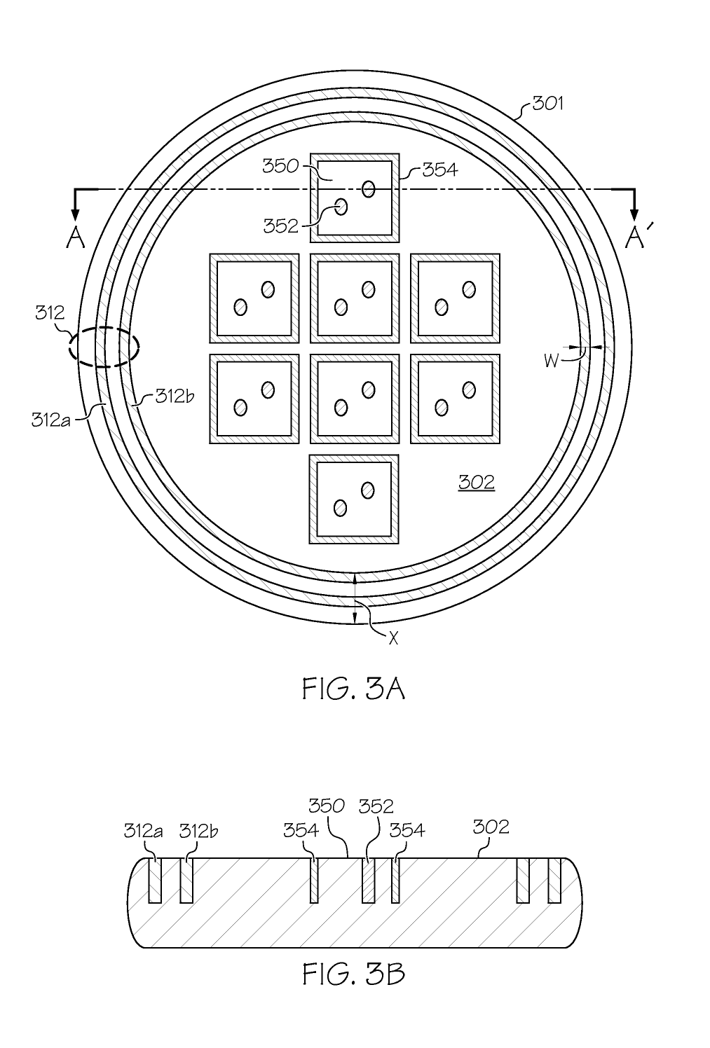

FIG. 3A is a top-down view of a semiconductor wafer in accordance with embodiments of the present invention. FIG. 3B is a cross section of the semiconductor structure shown in FIG. 3A along line A-A′. Wafer 302 has two wafer CSTs 312a and 312b on the inside of wafer edge 301. Together, CSTs 312a and 312b function as a crackstop 312. The width of a wafer CST, such as CST 312b is represented by W. In embodiments, W ranges from 500 nm to 10 microns. In embodiments, the width of one wafer CST may be the same or different from the width of another wafer CST. A distance from wafer edge 301 to an innermost edge of innermost wafer CST 312b is represented by X. In embodiments, X ranges from about 500 microns to about 3 millimeters. This defines the periphery of the wafer 302. At least one die 350 is formed on wafer 302. Each die 350 has at least one TSV 352, and at least one die CST 354 formed in the bulk silicon wafer 302. Die CSTs 354 are preferably formed simultaneously with TSVs 352, and may be formed by making a die CST 354 around the die to the same depth as the TSVs 352, and filling the die CSTs with the same material(s) used to fill the TSVs 352. The die CSTs may be formed and filled according to the same process as the TSVs 352.

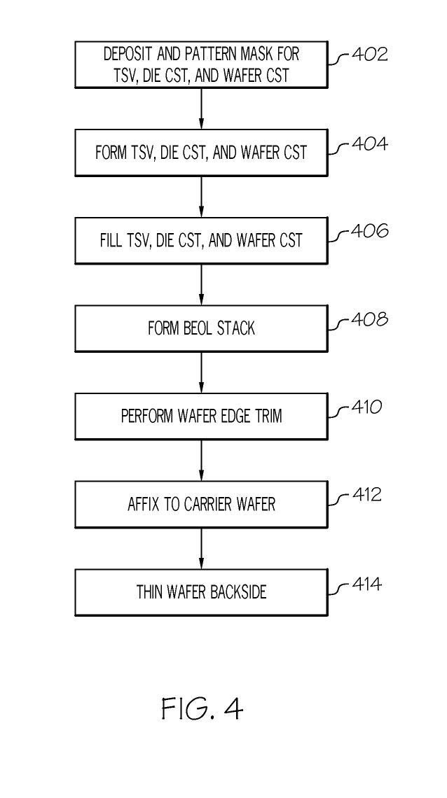

FIG. 4 is a flowchart indicating process steps for embodiments of the present invention. At 402, a mask is deposited and patterned for at least one of the following: a TSV, a die CST, and a wafer CST. At 404, the at least one of the TSV, die CST, and wafer CST is formed. In embodiments, a plurality or all of the TSV, die CST and wafer CST may be formed simultaneously. At 406, the TSV, die CST, and wafer CST are filled. In embodiments, the TSV, die CST, and wafer CST are filled. In embodiments, the TSV, die CST, and wafer CST may be simultaneously filled. At 408, a BEOL stack is formed. At 410, the wafer edge is trimmed. At 412, the BEOL stack is affixed to a carrier wafer. At 414, the backside of the wafer is thinned.

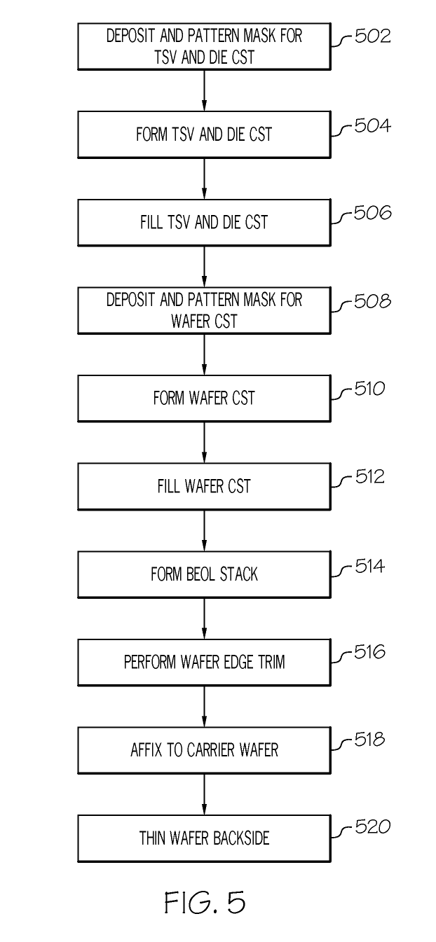

FIG. 5 is a flowchart indicating process steps for alternative embodiments of the present invention. At 502, a mask is deposited and patterned for TSV and die CST. At 504, a TSVs and a die CST are formed. In embodiments, the TSV and die CST are simultaneously formed. At 506, the TSV and die CST are filled. In embodiments, the TSV and die CST are simultaneously filled. At 508, a mask is deposited and patterned for the wafer CST. At 510, the wafer CST is formed. At 512, the wafer CST is filled. At 514, a BEOL stack is formed. At 516, a wafer edge trim is performed. At 518, the BEOL stack is affixed to a carrier wafer. At 520, the backside of the wafer is thinned.

While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A method for preventing damage in a bulk semiconductor wafer, comprising:
forming at least one trench within a periphery of the semiconductor wafer; and
filling the at least one trench with a fill material.

2. The method of claim 1, wherein forming at least one trench comprises forming a trench having a circular shape.

3. The method of claim 2, wherein the at least one trench comprises a first trench, and further comprising forming a second trench concentrically located within the first trench.

4. The method of claim 1, wherein filling the at least one trench with a fill material comprises filling the at least one trench with copper.

5. The method of claim 3, wherein the first trench and second trench are located less than 50 microns from an edge of the semiconductor wafer.

6. A method for preventing damage in a bulk semiconductor wafer comprising a plurality of die, the method comprising:
forming a die crackstop trench around each die;
forming a first wafer crackstop trench around a periphery of the semiconductor wafer; and
filling the die crackstop trench and the first wafer crackstop trench with a fill material.

7. The method of claim 6, wherein forming the first wafer crackstop trench comprises forming a trench having a circular shape.

8. The method of claim 7, further comprising forming a second wafer crackstop trench concentrically located within the first wafer crackstop trench.

9. The method of claim 6, wherein filling the die crackstop trench and the wafer crackstop trench with a fill material comprises filling the die crackstop trench and the wafer crackstop trench with copper.

10. The method of claim 8, wherein the first wafer crackstop trench and second wafer crackstop trench are located less than 50 microns from an edge of the semiconductor wafer.

11. A method for preventing damage in a bulk semiconductor wafer comprising a plurality of die, the method comprising:
forming a die crackstop trench around each die;
forming a wafer crackstop trench around a periphery of the semiconductor wafer;
filling the die crackstop trench with a first fill material; and
filling the wafer crackstop trench with a second fill material.

12. The method of claim 11, wherein forming the die crackstop trench comprises forming a trench of a first depth, and wherein forming the wafer crackstop trench comprises forming a trench of a second depth, wherein the second depth is less than the first depth.

13. The method of claim 12, wherein forming the wafer crackstop trench comprises forming the wafer crackstop trench with a depth ranging from about 10 microns to about 30 microns.

14. The method of claim 12, wherein forming the wafer crackstop trench comprises forming the wafer crackstop trench with a width ranging from about 500 nanometers to about 3 microns.

15. The method of claim 11, wherein filling the die crackstop trench with a first fill material comprises filling the die crackstop trench with copper.

16. The method of claim 15, wherein filling the wafer crackstop trench with a second fill material comprises filling the wafer crackstop trench with amorphous silicon.

17. The method of claim 15, wherein filling the wafer crackstop trench with a second fill material comprises filling the wafer crackstop trench with polysilicon.

18. The method of claim 15, wherein filling the wafer crackstop trench with a second fill material comprises filling the wafer crackstop trench with silicon oxide.

19. The method of claim 15, wherein filling the wafer crackstop trench with a second fill material comprises filling the wafer crackstop trench with titanium.

20. The method of claim 15, wherein filling the wafer crackstop trench with a second fill material comprises filling the wafer crackstop trench with tungsten.
